(19) United States
(12) Patent Application Publication
(10) Pub. No.: US 2025/0079231 A1
(43) Pub. Date: Mar. 6, 2025

(54) SUBSTRATE PROCESSING APPARATUS, ROTATION STATE DETECTION METHOD, METHOD OF MANUFACTURING SEMICONDUCTOR DEVICE AND NON-TRANSITORY COMPUTER-READABLE RECORDING MEDIUM

(71) Applicant: Kokusai Electric Corporation, Tokyo (JP)

(72) Inventors: Naofumi OHASHI, Toyama (JP); Shun MATSUI, Toyama (JP)

(21) Appl. No.: 18/819,422

(22) Filed: Aug. 29, 2024

(30) Foreign Application Priority Data
Aug. 31, 2023 (JP) 2023-141437

(51) Int. Cl. H01L 21/687; C23C 16/34; C23C 16/458; H01L 21/67

(52) U.S. Cl. CPC H01L 21/68764; C23C 16/345; C23C 16/4584; H01L 21/67017; H01L 21/67248; H01L 21/67259

(57) ABSTRACT

Provided is a technique capable of obtaining a desired processing quality for each of a plurality of substrates even when the plurality of substrates are processed while being rotated. There is provided a technique that includes: a process chamber in which a plurality of substrates are processed; a gas supplier configured to be capable of supplying a gas to the process chamber; a substrate support provided in the process chamber so as to be rotatable and configured to be capable of supporting the plurality of substrates in a circumferential arrangement; and a detector configured to detect a rotation state of the substrate support.

### CROSS REFERENCE TO RELATED APPLICATIONS

This non-provisional U.S. patent application is based on and claims priority under 35 U.S.C. § 119 of Japanese Patent Application No. 2023-141437 filed on Aug. 31, 2023, in the Japanese Patent Office, the entire contents of which are hereby incorporated by reference.

### TECHNICAL FIELD

The present disclosure relates to a substrate processing apparatus, a rotation state detection method, a method of manufacturing a semiconductor device and a non-transitory computer-readable recording medium.

### BACKGROUND

According to some related arts, as an apparatus used in a manufacturing process of a semiconductor device, a substrate processing apparatus may be used. For example, the substrate processing apparatus is configured to arrange a plurality of substrates in a circumferential arrangement and to perform a predetermined process such as a film forming process on each of the plurality of substrates by supplying a gas to each of the plurality of substrates while rotating the plurality of substrates.

When the plurality of substrates are processed while being rotated, a processing quality of each of the plurality of substrates may vary depending on a rotation state thereof.

### SUMMARY

According to the present disclosure, there is provided a technique capable of obtaining a desired processing quality for each of a plurality of substrates even when the plurality of substrates are processed while being rotated.

According to an aspect of the present disclosure, there is provided a technique that includes a process chamber in which a plurality of substrates are processed; a gas supplier configured to be capable of supplying a gas to the process chamber; a substrate support provided in the process chamber so as to be rotatable and configured to be capable of supporting the plurality of substrates in a circumferential arrangement; and a detector configured to detect a rotation state of the substrate support.

### BRIEF DESCRIPTION OF THE DRAWINGS

FIG. 1 is a diagram schematically illustrating a horizontal cross-section of a substrate processing apparatus according to one or more embodiments of the present disclosure when viewed from above.

FIG. 2 is a diagram schematically illustrating a vertical cross-section of the substrate processing apparatus according to the embodiments of the present disclosure, taken along a line α-α′ shown in FIG. 1

FIG. 3 is a diagram schematically illustrating a first specific example of a detector in the substrate processing apparatus according to the embodiments of the present disclosure, showing a state in which a substrate support is normal.

FIG. 4 is a diagram schematically illustrating the first specific example of the detector in the substrate processing apparatus according to the embodiments of the present disclosure, showing a state in which an abnormality has occurred in the substrate support.

FIG. 5 is a diagram schematically illustrating a second specific example of the detector in the substrate processing apparatus according to the embodiments of the present disclosure, showing the state in which the substrate support is normal.

FIG. 6 is a diagram schematically illustrating the second specific example of the detector in the substrate processing apparatus according to the embodiments of the present disclosure, showing the state in which the abnormality has occurred in the substrate support.

FIG. 7 is a diagram schematically illustrating a third specific example of the detector in the substrate processing apparatus according to the embodiments of the present disclosure, showing the state in which the substrate support is normal.

FIG. 8 is a diagram schematically illustrating the third specific example of the detector in the substrate processing apparatus according to the embodiments of the present disclosure, showing the state in which the abnormality has occurred in the substrate support.

FIGS. 9A to 9C are diagrams schematically illustrating exemplary configurations of a gas supplier in the substrate processing apparatus according to the embodiments of the present disclosure.

FIG. 10 is a block diagram schematically illustrating an exemplary functional configuration of a controller and related components of the substrate processing apparatus according to the embodiments of the present disclosure.

FIG. 11 is a flow chart schematically illustrating an exemplary sequence of a substrate processing performed by the substrate processing apparatus according to the embodiments of the present disclosure.

FIG. 12 is a diagram schematically illustrating specific examples of an execution timing of performing a rotation state monitoring while operating the substrate processing apparatus according to the embodiments of the present disclosure.

### DETAILED DESCRIPTION

Hereinafter, one or more embodiments (also simply referred to as “embodiments”) according to the technique of the present disclosure will be described with reference to the drawings.

### (1) Configuration of Substrate Processing Apparatus

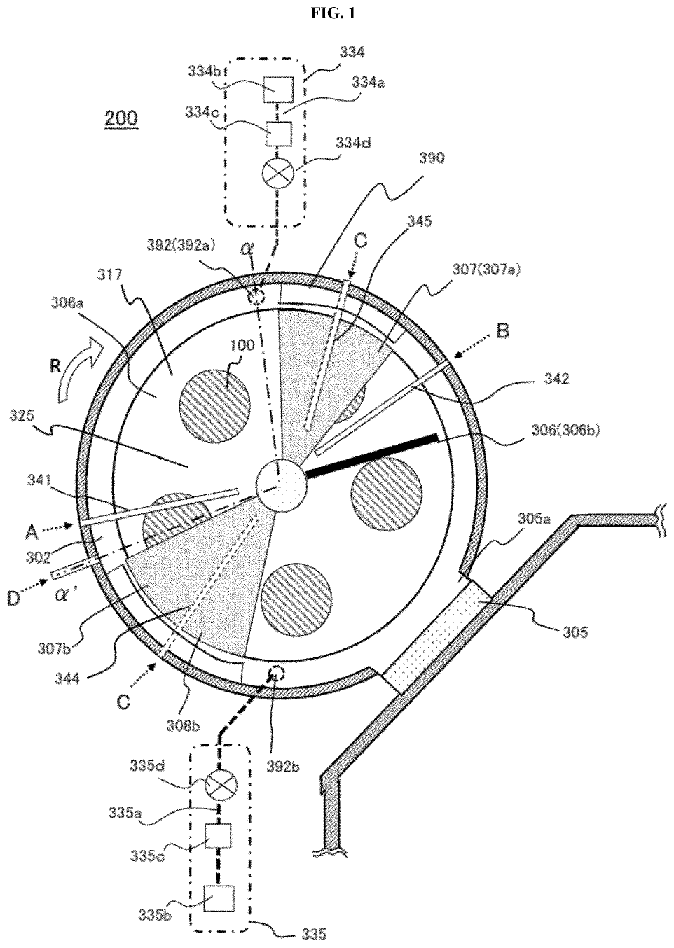

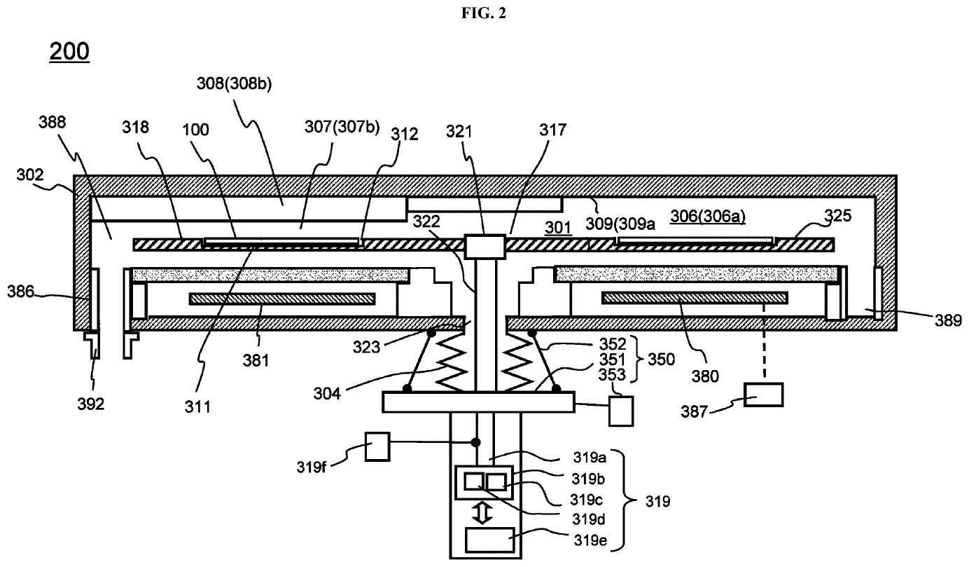

Hereinafter, one or more embodiments (also simply referred to as “embodiments”) of the technique of the present disclosure will be described in detail with reference to mainly FIGS. 1 and 2. The drawings used in the following descriptions are all schematic. For example, a relationship between dimensions of each component and a ratio of each component shown in the drawing may not always match the actual ones. Further, even between the drawings, the relationship between the dimensions of each component and the ratio of each component may not always match.

FIG. 1 is a diagram schematically illustrating a horizontal cross-section of a substrate processing apparatus 200 according to the embodiments of the present disclosure when viewed from above. FIG. 2 is a diagram schematically illustrating a vertical cross-section of the substrate processing apparatus 200 according to the embodiments of the present disclosure, taken along a line α-α′ shown in FIG. 1. Further, the line α-α′ is a line extending from a toward a center of a chamber 302 and further extending from the center of the chamber 302 toward α′.

A specific configuration of the substrate processing apparatus 200 will be described below. The substrate processing apparatus 200 is controlled by a controller 400 described later.

### Chamber

As shown in FIGS. 1 and 2, the substrate processing apparatus 200 is constituted mainly by the chamber 302 which is an airtight sealed vessel (process vessel) of a cylindrical shape. A process chamber 301 in which a plurality of substrates including a substrate 100 are processed is provided in the chamber 302. Hereinafter, the plurality of substrates including the substrate 100 may also be simply referred to as “substrates 100”. A gate valve 305 is connected to the chamber 302. The substrate 100 is loaded (transferred) into or unloaded (transferred) out of the chamber 302 through the gate valve 305 by a wafer transfer structure (not shown). The gate valve 305 is provided adjacent to a passage 305a. The substrate 100 is moved through the passage 305a.

In the process chamber 301, a process region 306 (which includes a first process region 306a and a second process region 306b) serving as a domain (region) to which a process gas such as a first gas and a second gas is supplied and a purge region 307 (which includes a first purge region 307a and a second purge region 307b) serving as a domain (region) to which a purge gas is supplied are provided. According to the present embodiments, the process region 306 and the purge region 307 are alternately arranged along a circumferential direction of the process chamber 301. For example, the first process region 306a serving as a first domain, the first purge region 307a serving as a first purge domain, the second process region 306b serving as a second domain and the second purge region 307b serving as a second purge domain are sequentially arranged along the circumferential direction in this order. As described later, for example, the first gas is supplied into the first process region 306a, the second gas is supplied into the second process region 306b, and an inert gas (that is, the purge gas) is supplied into the first purge region 307a and the second purge region 307b. As a result, a predetermined process (for example, a substrate processing) is performed with respect to the substrates 100 in accordance with the gas supplied into each region.

The purge region 307 (that is, the first purge region 307a and the second purge region 307b) is configured to spatially separate the first process region 306a and the second process region 306b. A ceiling 308 of the purge region 307 is disposed lower than a ceiling 309 of the process region 306. Specifically, a ceiling 308a is provided at the first purge region 307a and a ceiling 308b is provided at the second purge region 307b. By lowering each of the ceiling 308a and the ceiling 308b, it is possible to increase a pressure of a space in the purge region 307. By supplying the purge gas to the space described above, it is possible to partition the adjacent process region 306 (that is, the first process region 306a and the second process region 306b). In addition, by supplying the purge gas, it is possible to remove excess gases (undesired gases) on the substrates 100.

A substrate support 317 configured to support the substrates 100 is provided in the chamber 302. The substrate support 317 is made of a material capable of allowing a transmission of a heat, and is configured to transmit the heat radiated from a heater 380 described later. The substrate 100 is heated by the heat transmitted through the substrate support 317.

The substrate support 317 is provided so as to be freely rotatable within the chamber 302. Further, the substrate support 317 is configured such that the substrates 100 (for example, five substrates) can be arranged within the process chamber 301 on the same plane and along the same circumference along a rotation direction “R” shown in FIG. 1.

Thus, the substrate support 317 includes a substrate placing plate (also referred to as a “substrate mounting plate”) 318 serving as a rotating structure of a plate shape configured to support the substrates 100. Thereby, the substrate support 317 is capable of supporting the substrates 100 in a circumferential arrangement (that is, along the circumferential direction). The substrate placing plate 318 is supported by a support shaft (described later) disposed in the vicinity of the center of the chamber 302, and is configured to be rotatable about the support shaft as a rotation axis. In other words, the substrate support 317 is constituted by at least the substrate placing plate 318 and a shaft 322 (described later) serving as the support shaft configured to support the substrate placing plate 318.

For example, a surface of the substrate placing plate 318 is constituted by: a plurality of substrate placing surfaces including a substrate placing surface 311; and a substrate non-placing surface 325. Hereinafter, the plurality of substrate placing surfaces including the substrate placing surface 311 may also be simply referred to as substrate placing surfaces 311. The substrates 100 may be placed on the substrate placing surfaces 311, respectively. For example, the substrate placing surfaces 311 are arranged along a circle centered on a center of the substrate placing plate 318. That is, the substrate placing surfaces 311 are arranged at the same distance from the center of the substrate placing plate 318, and along the same circumference with equal intervals (for example, 72° intervals) therebetween. In FIG. 1, the illustration of the substrate placing surfaces 311 is omitted for simplification.

For example, the substrate placing surfaces 311 are provided on bottom surfaces of a plurality of concave structures including a concave structure 312, respectively. Hereinafter, the plurality of concave structures including the concave structure 312 may also be simply referred to as “concave structures 312”. For example, each of the concave structures 312 is of a circular shape when viewed from an upper surface of the substrate placing plate 318, and of a concave shape when viewed from a side surface of the substrate placing plate 318. It is preferable that a diameter of each of the concave structures 312 is slightly greater than a diameter of the substrate 100. For example, the substrate 100 may be placed on the substrate placing surface 311 by being placed on one of the concave structures 312.

The substrate placing plate 318 is fixed to a core structure 321. The core structure 321 is provided at the center of the substrate placing plate 318 and configured to fix the substrate placing plate 318 to the shaft 322 described later. The shaft 322 serving as the support shaft configured to support the substrate placing plate 318 is provided below the core structure 321. The shaft 322 supports the core structure 321.

A lower portion of the shaft 322 penetrates a hole 323 provided at a bottom of the chamber 302, and a bellows 304 provided outside the chamber 302 and capable of airtightly (hermetically) sealing the shaft 322 covers the lower portion of the shaft 322. In addition, an elevating and rotating structure 319 is provided at a lower end of the shaft 322. The elevating and rotating structure 319 may also be referred to as an “elevator/rotator 319”.

The elevator/rotator 319 mainly includes: a support shaft 319a configured to support the shaft 322; and an operating structure 319b configured to elevate/lower or rotate the support shaft 319a. For example, the operating structure 319b may include: an elevator (which is an elevating structure) 319c such as a motor configured to elevate and lower the support shaft 319a; and a rotator (which is a rotating structure) 319d such as a gear configured to rotate the support shaft 319a.

The elevator/rotator 319 may further include an instruction controller 319e serving as a part of the elevator/rotator 319 and configured to control the operating structure 319b to move the support shaft 319a up and down or to rotate the support shaft 319a. The instruction controller 319e is electrically connected to the controller 400. The operating structure 319b is controlled by the instruction controller 319e based on an instruction from the controller 400.

By operating the elevator/rotator 319 to rotate the shaft 322 and the substrate placing plate 318, the substrate support 317 is configured to be capable of rotating the substrates 100 placed on the substrate placing surfaces 311 along the circumferential direction. Further, by operating the elevator/rotator 319 to elevate or lower the shaft 322 and the substrate placing plate 318, the substrate support 317 is configured to be capable of elevating or lowering the substrates 100 placed on the substrate placing surfaces 311.

The elevator/rotator 319 may further include a rotation meter (such as a tachometer) 319f serving as a part of the elevator/rotator 319 and configured to detect values related to a rotation of the support shaft 319a or the shaft 322 supported thereby. For example, the rotation meter 319f is configured to be capable of detecting the values related to the rotation, such as the number of rotations and a value of a rotation speed when the support shaft 319a rotates and fluctuations in the number of rotations and the value of the rotation speed over time.

A posture controller 350 configured to control a posture of the substrate support 317 (that is, a part including at least the substrate placing plate 318 and the shaft 322) is provided between the shaft 322 and the elevator/rotator 319. For example, the posture controller 350 includes: a base 351 configured to support the shaft 322 and the elevator/rotator 319; and a plurality of actuators 352 configured to connect the base 351 to a lower surface of the chamber 302.

The actuators (for example, four or six actuators) 352 are evenly arranged around the shaft 322. Each of the actuators 352 is configured to be individually extendable and retractable. By changing a distance between the base 351 and the chamber 302 by individually extending and retracting the actuators 352, it is possible to control a tilt (inclination) of the base 351 with respect to the chamber 302. Thereby, it is possible to adjust the posture of the substrate support 317 (in particular, a tilt of the rotation axis caused by the shaft 322). Further, for example, as each of the actuators 352, a component such as an electric motor, an electromagnetic solenoid and an air cylinder may be used.

The posture controller 350 may further include a tilt regulator (which is a tilt adjusting structure) 353 serving as a part of the posture controller 350 and configured to instruct each of the actuators 352 to perform an extension and retraction operation. The tilt regulator 353 is electrically connected to the controller 400. The tilt regulator 353 is configured to control the extension and retraction operation of each of the actuators 352 based on an instruction from the controller 400.

In the chamber 302, a heater structure 381 with the heater 380 serving as a heating structure (heating device) embedded therein is disposed below the substrate placing plate 318. The heater 380 is disposed so as to face a lower surface of the substrate placing plate 318, and is configured to heat each of the substrates 100 placed on the substrate placing plate 318. The heater 380 is provided in the circumferential direction in accordance with a shape of the chamber 302. The heater 380 may be divided into a plurality of zones along the circumferential direction. A heater temperature controller 387 is connected to the heater 380. The heater temperature controller 387 is electrically connected to the controller 400 described later, and is configured to control a supply of the electric power to the heater 380 in accordance with an instruction from the controller 400 to perform a temperature control. When the heater 380 is divided into the plurality of zones, the heater temperature controller 387 is configured to be capable of individually performing the temperature control for each of the plurality of zones.

An exhaust buffer structure 386 is disposed at an outer periphery of the substrate placing plate 318. The exhaust buffer structure 386 includes an exhaust groove 388 and an exhaust buffer space 389. Each of the exhaust groove 388 and the exhaust buffer space 389 is arranged in the circumferential direction in accordance with the shape of the chamber 302.

A plurality of exhaust holes 392 are provided at a bottom of the exhaust buffer structure 386. Gases supplied into the process chamber 301 are exhausted through the plurality of exhaust holes 392. Each of the gases is exhausted through the plurality of exhaust holes 392 via the exhaust groove 388 and the exhaust buffer space 389.

### Detector

Subsequently, a detector (which is a detecting structure) configured to detect a rotation state of the substrate support 317 will be described mainly with reference to FIGS. 2, 3, 4, 5, 6, 7 and 8.

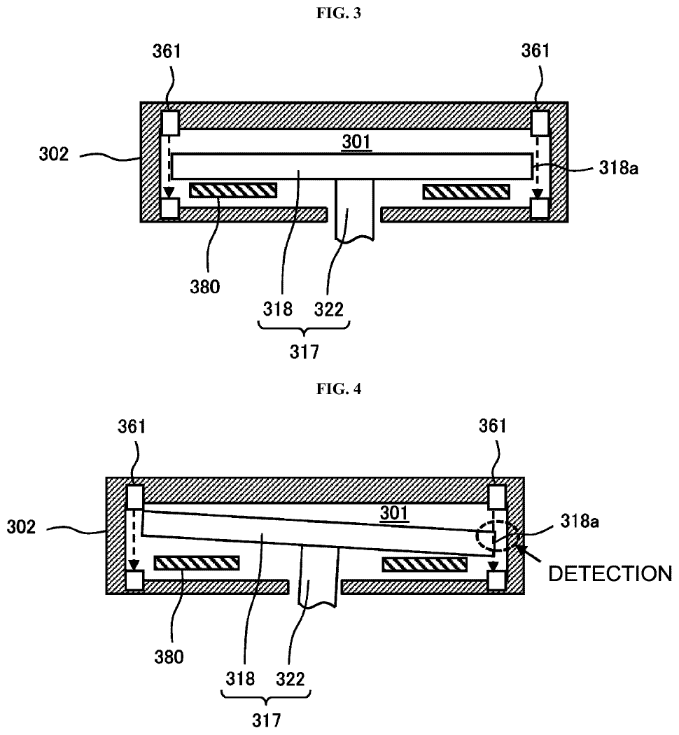

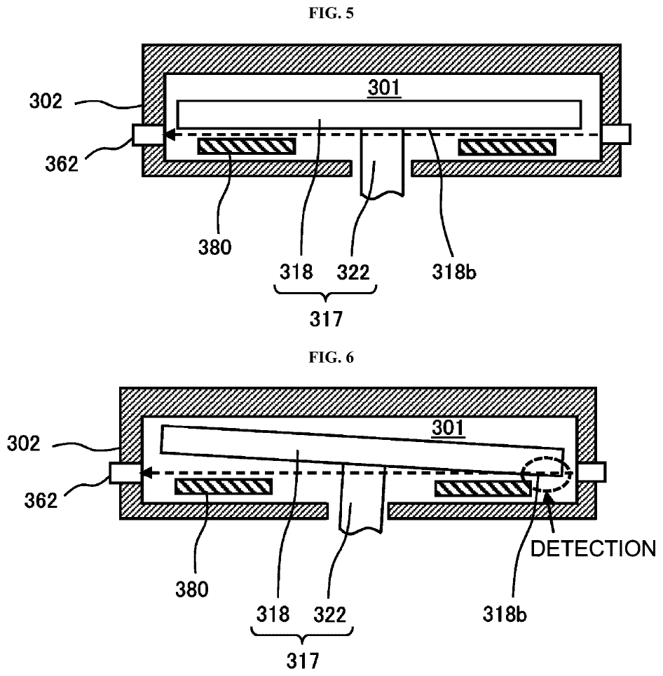

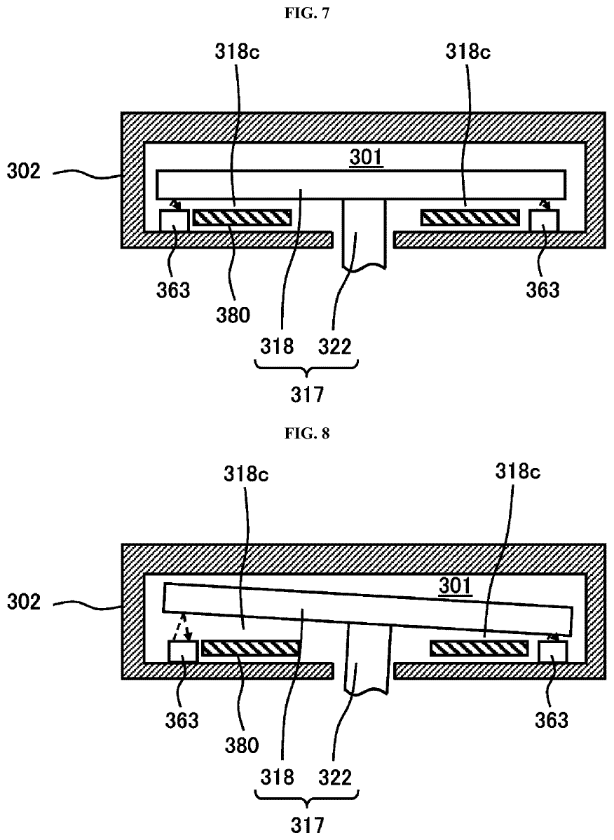

FIGS. 3 and 4 are diagrams schematically illustrating a first specific example of the detector in the substrate processing apparatus 200 according to the present embodiments. FIGS. 5 and 6 are diagrams schematically illustrating a second specific example of the detector in the substrate processing apparatus 200 according to the present embodiments. FIGS. 7 and 8 are diagrams schematically illustrating a third specific example of the detector in the substrate processing apparatus 200 according to the present embodiments.

The substrate processing apparatus 200 according to the present embodiments includes the detector configured to detect the rotation state of the substrate support 317 in the chamber 302. The rotation state of the substrate support 317 may refer to a state of the substrate placing plate 318 and a state of the shaft 322 when the substrate placing plate 318 is rotated around the shaft 322 as the rotation axis. More specifically, the rotation state of the substrate support 317 refers to, in particular, a presence or absence of an abnormality in the state of the substrate placing plate 318 when the substrate placing plate 318 is rotated. For example, the abnormality may include a tilt of the rotation axis, a bending of the substrate placing plate 318, a rotational fluctuation of the substrate placing plate 318 and the like when the substrate placing plate 318 is rotated.

For example, as shown in FIGS. 3 and 4, the chamber 302 may include a sensor 361 (which serves as the detector) configured to detect a position of an edge 318a. The edge 318a is an outer circumferential edge of the substrate placing plate 318. For example, the sensor 361 is configured as a transmissive photoelectric sensor in which a light emitter and a light receiver are arranged such that a sensing light passes along a side of the edge 318a. However, as long as it is possible to detect the position of the edge 318a, a reflective photoelectric sensor may be used as the sensor 361 instead of the transmissive photoelectric sensor. Further, as long as it is possible to detect the position of the edge 318a, a sensor of another detection type (for example, a proximity sensor) may be used as the sensor 361 instead of a photoelectric sensor such as the transmissive photoelectric sensor.

By the sensing light passing along the side of the edge 318a of the substrate placing plate 318, the sensor 361 is configured to be capable of detecting a presence or absence of the edge 318a of the substrate placing plate 318. Therefore, for example, as shown in FIG. 4, in a case where the rotation axis tilts when the substrate placing plate 318 is rotated, since the edge 318a blocks the sensing light, the tilt of the rotation axis is detected by the sensor 361.

Further, it is preferable that a plurality of sensors including the sensor 361 are arranged in the circumferential direction in accordance with an outer peripheral shape of the substrate placing plate 318. Hereinafter, the plurality of sensors including the sensor 361 may also be simply referred to as “sensors 361”. By providing the sensors 361 in a manner described above, it is possible to detect the tilt of the rotation axis regardless of any tilting direction. However, as long as a directional dependency of a tilt detection can be eliminated, there is no particular limit to the number of the sensors 361 arranged in a manner described above.

Further, for example, as shown in FIGS. 5 and 6, the chamber 302 may include a sensor 362 (which serves as the detector) arranged such that the sensing light passes along a plate surface of the substrate placing plate 318 (in particular, a lower surface 318b located opposite to the substrate placing surface 311). For example, the sensor 362 is configured as a transmissive photoelectric sensor in which a light emitter and a light receiver are arranged such that the sensing light passes along the lower surface 318b in the vicinity of the lower surface 318b of the substrate placing plate 318. However, as long as it is possible to detect a position of the lower surface 318b of the substrate placing plate 318, a reflective photoelectric sensor may be used as the sensor 362 instead of the transmissive photoelectric sensor. Further, as long as it is possible to detect the position of the plate surface (lower surface 318b) of the substrate placing plate 318, a sensor of another detection type (for example, a proximity sensor) may be used as the sensor 362 instead of a photoelectric sensor such as the transmissive photoelectric sensor.

By the sensing light passing along the vicinity of the plate surface of the substrate placing plate 318, the sensor 362 is configured to be capable of detecting a presence or absence of the plate surface of the substrate placing plate 318. Therefore, for example, as shown in FIG. 6, in a case where the rotation axis tilts when the substrate placing plate 318 is rotated, since the lower surface 318b of the substrate placing plate 318 blocks the sensing light, the tilt of the rotation axis is detected by the sensor 362. Further, not only in the case where the rotation axis tilts, but also in a case where the substrate placing plate 318 bends (that is, the substrate placing plate 318 sags in the direction of gravity), since the lower surface 318b of the substrate placing plate 318 blocks the sensing light, the bending of the substrate placing plate 318 is detected by the sensor 362.

Further, for example, as shown in FIGS. 7 and 8, the chamber 302 may include a sensor 363 (which serves as the detector) configured to detect a distance (gap 318c) between the substrate placing plate 318 and the heater 380. For example, the sensor 363 is configured as a laser length measurement sensor disposed in the vicinity of the heater 380 and configured to detect a distance from a position thereof to the lower surface of the substrate placing plate 318. However, as long as it is possible to detect a size of the gap 318c, a sensor of another detection type (for example, a proximity sensor) may be used as the sensor 363 instead of the laser length measurement sensor.

By detecting the distance between the substrate placing plate 318 and the heater 380, the sensor 363 is configured to be capable of detecting whether the size of the gap 318c is constant (that is, whether a predetermined size is maintained). Therefore, for example, as shown in FIG. 8, in a case where the rotation axis tilts when the substrate placing plate 318 is rotated, since the distance between the substrate placing plate 318 and the heater 380 varies, the tilt of the rotation axis is detected by the sensor 363. Further, not only in the case where the rotation axis tilts, but also in a case where the substrate placing plate 318 bends (that is, the substrate placing plate 318 sags in the direction of gravity), since the distance between the substrate placing plate 318 and the heater 380 varies, the bending of the substrate placing plate 318 is detected by the sensor 363.

As described above, the detector is configured to detect the tilt of the substrate placing plate 318, the bending of the substrate placing plate 318 or both of the tilt and the bending of the substrate placing plate 318. As long as it is possible to detect the tilt, the bending or both of the tilt and the bending, the detector may include one of the sensors 361, 362 and 363 described above, or may include an appropriate combination of two or more of the sensors 361, 362 and 363. By appropriately combining the sensors 361, 362 and 363, it is possible to reliably detect both of the tilt and the bending of the substrate placing plate 318.

A detection of the tilt, the bending or the like of the substrate placing plate 318 is not limited to that using the sensors 361, 362 and 363 described above, and may be performed as follows. For example, the detector may include a sensor configured to detect a distance (gap) (or distances (gaps)) between the substrate placing plate 318 and at least one among nozzles 341, 342, 344 and 345 of a gas supplier described later. Such a sensor may be configured in the same manner as the sensor 363 described above. Even with such a configuration, the detector is configured to detect the tilt, the bending or the like of the substrate placing plate 318.

As long as it is possible to detect the rotation state of the substrate support 317, the detector is not limited to that configured to detect the tilt, the bending or the like of the substrate placing plate 318. For example, the detector may be configured to detect the rotational fluctuation when the substrate placing plate 318 is rotated, as the rotation state of the substrate support 317. A detection of the rotational fluctuation may be performed in addition to the detection of the tilt, the bending or the like of the substrate placing plate 318, or may be performed instead of the detection of the tilt, the bending or the like of the substrate placing plate 318.

As an example of the detector configured to detect the rotational fluctuation, for example, by using the rotation meter 319f of the elevator/rotator 319 shown in FIG. 2, the detector is configured to monitor the number of rotations or the rotation speed when the substrate placing plate 318 is rotated and to detect an occurrence of the rotational fluctuation when a change in the number of rotations or the rotation speed exceeds a pre-set allowable value.

Further, as another example of the detector configured to detect the rotational fluctuation, for example, in a case where the operating structure 319b of the elevator/rotator 319 shown in FIG. 2 includes an electric motor serving as a drive source configured to rotate the shaft 322 and the support shaft 319a, the detector is configured to monitor an amount of the power supplied to the electric motor and to detect the occurrence of the rotational fluctuation when a change in the power exceeds a pre-set allowable value.

The detector may perform the following detection of the rotation state of the substrate support 317. For example, the detector may include a vibration sensor configured to detect a vibration of the shaft 322 and a variation of the support shaft 319a when the substrate placing plate 318 is rotated. In such a case, by comparing a magnitude of a vibration value from the vibration sensor with a pre-set threshold value, it is possible to detect signs such as a defect in a bearing (such as a fluid seal) of the shaft 322 or the support shaft 319a, an eccentricity of the rotation axis and the like. Thereby, it is possible to indirectly detect the rotation state of the substrate support 317.

### Gas Supplier

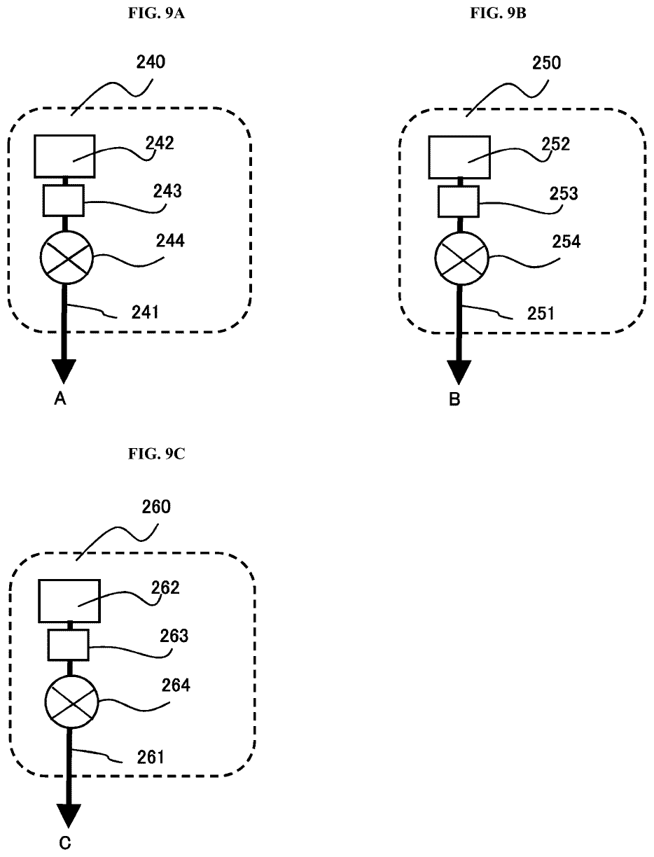

Subsequently, the gas supplier (which is a gas supply structure or a gas supply system) configured to supply the gases into the chamber 302 will be described mainly with reference to FIGS. 1 and 9A through 9C. FIGS. 9A through 9C are diagrams schematically illustrating exemplary configurations of the gas supplier in the substrate processing apparatus 200 according to the present embodiments.

The nozzles 341, 342, 344 and 345 are provided in the chamber 302. A location indicated by a reference character “A” shown in FIG. 1 is connected to a location indicated by a reference character “A” shown in FIG. 9A. That is, the nozzle 341 is connected to a supply pipe 241. A location indicated by a reference character “B” shown in FIG. 1 is connected to a location indicated by a reference character “B” shown in FIG. 9B. That is, the nozzle 342 is connected to a supply pipe 251. A location indicated by a reference character “C” shown in FIG. 1 is connected to a location indicated by a reference character “C” shown in FIG. 9C. That is, each of the nozzles 344 and 345 is connected to a supply pipe 261.

FIG. 9A is a diagram schematically illustrating an exemplary configuration of a first gas supplier (which is a first gas supply structure or a first gas supply system) 240 serving as a part of the gas supplier. A first gas supply source 242, a mass flow controller (MFC) 243 serving as a flow rate controller (flow rate control structure) and a valve 244 serving as an opening/closing valve are sequentially provided at the supply pipe (first gas supply pipe) 241 of the first gas supplier 240 in this order from an upstream side to a downstream side of the first gas supply pipe 241 in a gas flow direction.

A gas containing a first element (hereinafter, also referred to as the “first gas”) is mainly supplied through the first gas supply pipe 241 of the first gas supplier 240. That is, the first gas is supplied to the nozzle 341 through the MFC 243, the valve 244 and the first gas supply pipe 241. Then, the first gas is supplied to the first process region 306a through nozzle 341.

The first gas is one of process gases, and refers to a source gas containing the first element. According to the present embodiments, for example, the first element is silicon (Si). That is, the first gas is a silicon gas (also referred to as a “silicon-containing gas”) which is a gas containing silicon as a primary component. Specifically, dichlorosilane (SiH₂Cl₂, abbreviated as DCS) gas may be used as the silicon-containing gas.

The first gas supplier 240 is constituted mainly by the first gas supply pipe 241, the MFC 243, the valve 244 and the nozzle 341. The first gas supplier 240 may further include the first gas supply source 242.

FIG. 9B is a diagram schematically illustrating an exemplary configuration of a second gas supplier (which is a second gas supply structure or a second gas supply system) 250 serving as a part of the gas supplier. A second gas supply source 252, a mass flow controller (MFC) 253 serving as a flow rate controller (flow rate control structure) and a valve 254 serving as an opening/closing valve are sequentially provided at the supply pipe (second gas supply pipe) 251 of the second gas supplier 250 in this order from an upstream side to a downstream side of the second gas supply pipe 251 in the gas flow direction.

A reactive gas reacting with the first gas (hereinafter, also referred to as the “second gas”) is mainly supplied through the second gas supply pipe 251 of the second gas supplier 250. That is, the second gas is supplied to the nozzle 342 through the MFC 253, the valve 254 and the second gas supply pipe 251. Then, the second gas is supplied to the second process region 306b through nozzle 342.

The second gas is one of the process gases. For example, the second gas refers to a nitrogen-containing gas containing nitrogen (N) as a primary component. For example, ammonia (NH₃) gas may be used as the nitrogen-containing gas.

The second gas supplier 250 is constituted mainly by the second gas supply pipe 251, the MFC 253, the valve 254 and the nozzle 342. The second gas supplier 250 may further include the second gas supply source 252. Since the second gas supplier 250 is configured to supply the reactive gas, the second gas supplier 250 may also be referred to as a “reactive gas supplier” 250 which is a reactive gas supply structure or a reactive gas supply system.

FIG. 9C is a diagram schematically illustrating an exemplary configuration of a purge gas supplier (which is a purge gas supply structure or a purge gas supply system) 260 serving as a part of the gas supplier. The purge gas supplier 260 may also be referred to as an “inert gas supplier 260” which is an inert gas supply structure or an inert gas supply system. A purge gas supply source 262, a mass flow controller (MFC) 263 serving as a flow rate controller (flow rate control structure) and a valve 264 serving as an opening/closing valve are sequentially provided at the supply pipe (purge gas supply pipe) 261 of the purge gas supplier 260 in this order from an upstream side to a downstream side of the purge gas supply pipe 261 in the gas flow direction.

The purge gas (inert gas) is supplied through the purge gas supply pipe 261 of the purge gas supplier 260. That is, the purge gas is supplied to each of the nozzle 344 and the nozzle 345 through the MFC 263, the valve 264 and the purge gas supply pipe 261. Then, the purge gas is supplied to the first purge region 307a through the nozzle 344, and is supplied to the second purge region 307b through the nozzle 345.

The purge gas refers to a gas that does not react with the first gas and the second gas. An inner atmosphere of the process chamber 301 can be purged by the purge gas. For example, nitrogen (N₂) gas may be used as the purge gas.

The purge gas supplier 260 is constituted mainly by the purge gas supply pipe 261, the MFC 263, the valve 264, the nozzle 344 and the nozzle 345. The purge gas supplier 260 may further include the purge gas supply source 262.

The first gas supplier 240 and the second gas supplier 250 may also be collectively or individually referred to as a “process gas supplier” which is a process gas supply structure or a process gas supply system. The process gas supplier may further include the purge gas supplier 260.

### Gas Exhauster

Subsequently, a gas exhauster (which is a gas exhaust structure or a gas exhaust system) configured to exhaust the gases from the chamber 302 will be described mainly with reference to FIGS. 1 and 2.

The plurality of exhaust holes 392 are provided at a lower portion of the chamber 302. The plurality of exhaust holes 392 are provided for each process region 306. For example, an exhaust hole 392a among the exhaust holes 392 is provided at a location corresponding to the first process region 306a, and an exhaust hole 392b among the exhaust holes 392 is provided at a location corresponding to the second process region 306b.

An exhaust pipe 334a serving as a part of a first exhauster (which is a first exhaust structure) 334 is provided so as to communicate with the exhaust hole 392a. A vacuum pump 334b serving as a vacuum exhaust apparatus is connected to the exhaust pipe 334a via a valve 334d serving as an opening/closing valve and an APC (Automatic Pressure Controller) valve 334c serving as a pressure regulator (which is a pressure adjusting structure). The vacuum pump 334b is configured to vacuum-exhaust the inner atmosphere of the process chamber 301 such that an inner pressure of the process chamber 301 reaches and is maintained at a predetermined pressure (vacuum degree). The exhaust pipe 334a, the valve 334d and the APC valve 334c may also be collectively referred to as the first exhauster 334. The first exhauster 334 may further include the vacuum pump 334b.

Similarly, a second exhauster (which is a second exhaust structure) 335 is connected to the exhaust hole 392b so as to communicate with the exhaust hole 392a. An exhaust pipe 335a, a valve 335d and an APC valve 335c may also be collectively referred to as the second exhauster 335. The second exhauster 335 may further include a vacuum pump 335b. In addition, the first exhauster 334 and the second exhauster 335 may also be collectively referred to as the “gas exhauster”.

### Controller

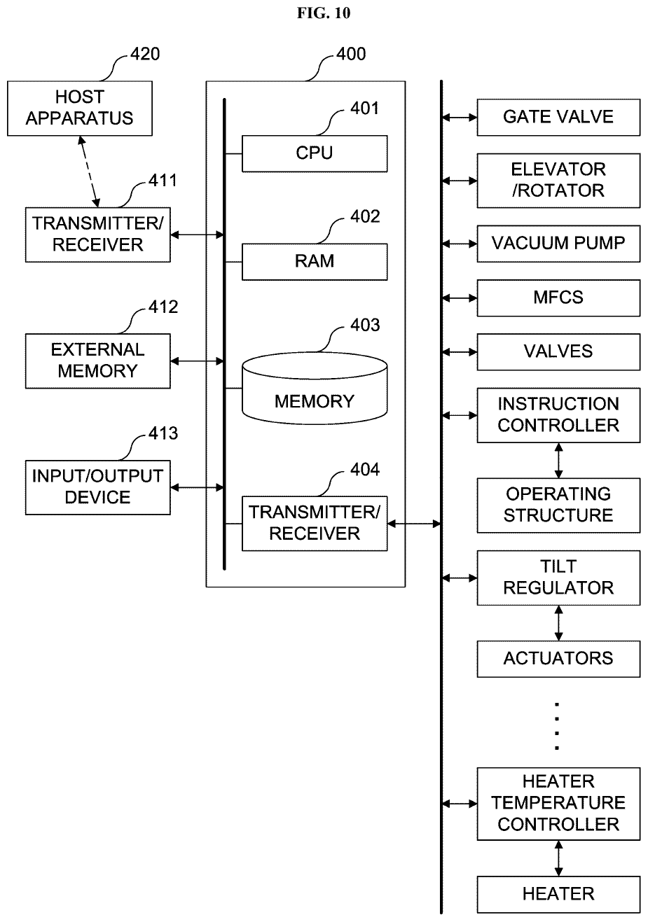

The substrate processing apparatus 200 configured as described above is controlled by the controller 400 serving as a control structure (control apparatus). Hereinafter, the controller 400 will be described mainly with reference to FIG. 10. FIG. 10 is a block diagram schematically illustrating an exemplary functional configuration of the controller 400 and related components of the substrate processing apparatus 200 according to the present embodiments.

The substrate processing apparatus 200 includes the controller 400 configured to control operations of components of the substrate processing apparatus 200 such as the gas supplier, the elevator/rotator 319, the valves described above and the MFCs described above. The controller 400 includes at least a CPU (Central Processing Unit) 401 serving as an arithmetic processor, a RAM (Random Access Memory) 402 serving as a temporary memory, a memory 403 and a transmitter/receiver 404. The controller 400 is connected to the components of the substrate processing apparatus 200 via the transmitter/receiver 404, calls a program or a recipe from the memory 403 in accordance with an instruction from a host controller or a user, and controls the operations of the components of the substrate processing apparatus 200 in accordance with the contents of the instruction. For example, the controller 400 may be embodied by a dedicated computer or by a general-purpose computer. According to the present embodiments, for example, the controller 400 may be embodied by preparing an external memory 412 storing the program and by installing the program onto the general-purpose computer using the external memory 412. For example, the external memory 412 may include a magnetic tape, a magnetic disk such as a flexible disk and a hard disk, an optical disk such as a CD and a DVD, a magneto-optical disk such as an MO and a semiconductor memory such as a USB memory (USB flash drive) and a memory card. A method of providing the program to the computer is not limited to that using the external memory 412. For example, the program may be supplied to the computer (general-purpose computer) using a communication interface such as the Internet and a dedicated line. The program may also be provided to the computer without using the external memory 412 by receiving information (that is, the program) from a host apparatus 420 via a transmitter/receiver 411. In addition, a user can input an instruction to the controller 400 using an input/output device 413 such as a keyboard and a touch panel.

According to the present embodiments, the memory 403 or the external memory 412 may be embodied by a non-transitory computer readable recording medium. Hereafter, the memory 403 and the external memory 412 may be collectively or individually referred to as a “recording medium”. Thus, in the present specification, the term “recording medium” may refer to the memory 403 alone, may refer to the external memory 412 alone, or may refer to both of the memory 403 and the external memory 412.

### (2) Substrate Processing

Subsequently, a procedure of performing the substrate processing (which is a part of a manufacturing process of a semiconductor device) using the substrate processing apparatus 200 configured as described above will be described. The substrate processing will be described by way of an example in which a silicon nitride film (SiN film) is formed as a film on the substrate 100 using the silicon-containing gas as the first gas and the NH₃ gas as the second gas.

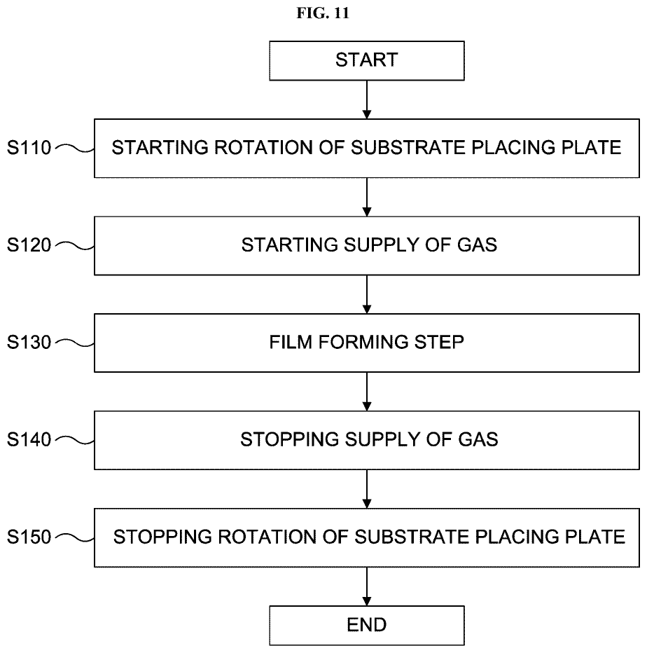

Hereinafter, the substrate processing will be described mainly with reference to FIG. 11. FIG. 11 is a flow chart schematically illustrating an exemplary sequence of the substrate processing performed by the substrate processing apparatus 200 according to the present embodiments. In the following description, the operations of the components constituting the substrate processing apparatus 200 are controlled by the controller 400.

### Substrate Loading and Placing Step

In the substrate processing, first, a substrate loading and placing step is performed. In FIG. 11, the illustration of the substrate loading and placing step is omitted.

In the substrate loading and placing step, the concave structure 312 is moved to a position adjacent to the gate valve 305 by rotating the substrate placing plate 318. Then, the substrate 100 is placed on one of the substrate placing surfaces 311 from a transfer chamber by using the wafer transfer structure 500.

After the substrate 100 is placed on the above-mentioned one of the substrate placing surfaces 311, the substrate placing plate 318 is rotated until another one of the substrate placing surfaces 311, where the substrate 100 is not placed, faces the gate valve 305. Thereafter, another one of the substrates 100 is placed on the above-mentioned another one of the substrate placing surfaces 311. An operation described above is repeatedly performed until the substrates 100 are placed on an entirety of the substrate placing surfaces 311.

When the substrate 100 is placed on the substrate placing plate 318, the electric power is supplied to the heater 380 in advance such that a temperature (surface temperature) of the substrate 100 is adjusted to a predetermined temperature. For example, the predetermined temperature of the substrate 100 according to the present embodiments may be set to a temperature of 400° C. or more and 500° C. or less. The heat radiated from the heater 380 is applied to a back surface of the substrate 100 via the substrate placing plate 318. It is preferable that the electric power is continuously supplied to the heater 380 from the substrate loading and placing step until at least a substrate unloading step described later is completed.

### Step of Starting Rotation of Substrate Placing Plate

After the substrates 100 are placed on an entirety of the concave structures 312, a step S110 of starting the rotation of the substrate placing plate 318 is performed. In the step S110 of starting the rotation of the substrate placing plate 318, the controller 400 controls the elevator/rotator 319 to rotate the substrate placing plate 318 in the direction “R” shown in FIG. 1. By rotating the substrate placing plate 318, the substrate 100 is moved to the first process region 306a, the first purge region 307a, the second process region 306b and the second purge region 307b sequentially in this order.

### Step of Starting Supply of Gas

When the substrate 100 is heated to a desired temperature in the substrate loading and placing step and when the rotation speed of the substrate placing plate 318 reaches and is maintained at a desired rotation speed in the step S110 of starting the rotation of the substrate placing plate 318, a step S120 of starting a supply of the gas is then performed. In the step S120 of starting the supply of the gas, the valve 244 is opened to start a supply of the silicon-containing gas into the first process region 306a. In parallel with the supply of the silicon-containing gas, the valve 254 is opened to start a supply of the NH₃ gas into the second process region 306b.

In the present step, a flow rate of the silicon-containing gas is adjusted by the MFC 243 to a predetermined flow rate. For example, the predetermined flow rate of the silicon-containing gas may be set to a flow rate of 50 sccm or more and 500 sccm or less.

Further, in the present step, a flow rate of the NH₃ gas is adjusted by the MFC 253 to a predetermined flow rate. For example, the predetermined flow rate of the NH₃ gas may be set to a flow rate of 100 sccm or more and 5,000 sccm or less.

In addition, after the substrate loading and placing step, the process chamber 301 is exhausted by the first exhauster 334 and the second exhauster 335, and the N₂ gas serving as the purge gas is supplied into the first purge region 307a and the second purge region 307b through the purge gas supplier 260.

### Film Forming Step

Subsequently, a film forming step S130 is performed. In the film forming step S130, a silicon-containing layer is formed on the substrate 100 in the first process region 306a. After the substrate 100 is rotated to the second process region 306b, by reacting the silicon-containing layer with the NH₃ gas in the second process region 306b, the silicon containing film (such as the SiN film) is formed on the substrate 100. Then, the substrate placing plate 318 is rotated a predetermined number of times such that the silicon containing film (such as the SiN film) on the substrate 100 is obtained with a desired thickness.

### Step of Stopping Supply of Gas

After the substrate placing plate 318 is rotated the predetermined number of times in the film forming step S130, a step S140 of stopping the supply of the gas is performed. In the step S140 of stopping the supply of the gas, the valve 244 is closed to stop the supply of the silicon-containing gas to the first process region 306a and the valve 254 is closed to stop the supply of the NH3 gas to the second process region 306b.

### Step of Stopping Rotation of Substrate Placing Plate

After the step S140 of stopping the supply of the gas, a step S150 of stopping the rotation of the substrate placing plate 318 is performed. In the step S150 of stopping the rotation of the substrate placing plate 318, the rotation of the substrate placing plate 318 is stopped.

### Substrate Unloading Step

After the step S150 of stopping the rotation of the substrate placing plate 318, the substrate unloading step is performed. In FIG. 11, the illustration of the substrate unloading step is omitted.

In the substrate unloading step, the substrate placing plate 318 is rotated to move the substrate 100 (which is to be unloaded) to the position adjacent to the gate valve 305. Thereafter, the substrate 100 to be unloaded is transferred (unloaded) out of the chamber 302 in a manner reverse to that of the substrate loading and placing step. An operation described above is repeatedly performed until an entirety of the substrates 100 are unloaded out of the chamber 302.

### (3) Rotation Control Process

As described above, in the substrate processing, by rotating the substrate placing plate 318, each of the substrates 100 on the substrate placing plate 318 is processed. Therefore, depending on a rotation state of the substrate placing plate 318, for example, a processing quality of each of the substrates 100 may vary.

For example, in a case where the rotation axis of the substrate placing plate 318 tilts, the substrate placing surface 311 on the substrate placing plate 318 also tilts accordingly. In such a sate, when the substrate placing plate 318 is rotated, the tilt may cause variations in a distance such as a distance between the substrate 100 on the substrate placing surface 311 and the heater 380 and a distance between the substrate 100 and at least one among the nozzles 341, 342, 344 and 345 configured to supply the gas. In such a case, a substrate processing state may differ between each of the substrates 100 placed on the substrate placing plate 318 or may differ between lots of the substrates 100 to be processed. As a result, the processing quality of each of the substrates 100 may vary.

Further, when the heat from the heater 380 accumulates, the substrate placing plate 318 may bend. When the substrate placing plate 318 is bent, similar to the case of the tilt described above, the substrate processing state may differ between each of the substrates 100 or may differ between the lots of the substrates 100. As a result, the processing quality of each of the substrates 100 may vary.

Further, in a case where the rotational fluctuation (such as a fluctuation in the rotation speed) occurs when the substrate placing plate 318 is rotated, a time for the substrate 100 to pass through each of the regions 306a, 307a, 306b and 307b may vary. Then, for example, an amount of the gas exposed to the substrate 100 may vary. For example, an amount of a particular gas exposed to the substrate 100 may increase and an amount of another gas exposed to the substrate 100 may decrease. Then, the substrate processing state may differ between each of the substrates 100 or may differ between the lots of the substrates 100. As a result, the processing quality of each of the substrates 100 may vary.

That is, when there is the abnormality in the rotation state of the substrate placing plate 318 during the substrate processing, it may cause the variation in the processing quality of each of the substrates 100. As a result, it may not be possible to obtain the substrate 100 with a desired processing quality.

Therefore, before performing the substrate processing, the substrate processing apparatus 200 according to the present embodiments is configured to perform a rotation control process using the detector under control of the controller 400, as described below. The rotation control process is a process in which the detector monitors the rotation state of the substrate support 317 and controls the rotation state of the substrate support 317 based on a monitoring result. After the rotation control process is performed, the substrate processing including the supply of the gas into the process chamber 301 is performed.

### Monitoring

In the rotation control process, first, the rotation state of the substrate support 317 is monitored (that is, a rotation state monitoring of the substrate support 317 is performed). The rotation state monitoring is performed using the detector. Specifically, in the rotation state monitoring serving as a rotation state detection method, a step of rotating the substrate placing plate 318 of the substrate support 317 and a step of detecting the rotation state of the substrate support 317 using the detector are performed.

For example, in a case where the detector includes the sensor 361, as shown in FIG. 4, when the rotation axis of the substrate placing plate 318 tilts, such a tilt is detected by the sensor 361. Therefore, by monitoring a result (detection result) detected by the sensor 361, it is possible to detect the presence or absence of the abnormality in the rotation state of the substrate placing plate 318 (in particular, the tilt of the rotation axis thereof). In particular, when the detector includes the plurality of sensors 361, it is possible to detect the presence or absence of the abnormality in the rotation state with a high accuracy.

Further, for example, in a case where the detector includes the sensor 362, as shown in FIG. 6, when the rotation axis of the substrate placing plate 318 tilts, such a tilt is detected by the sensor 362. The same also applies to a case where the substrate placing plate 318 bends (that is, the substrate placing plate 318 sags in the direction of gravity). Therefore, by monitoring a result (detection result) detected by the sensor 362, it is possible to detect the presence or absence of the abnormality in the rotation state of the substrate placing plate 318 (in particular, the tilt of the rotation axis thereof and the bending of the substrate placing plate 318).

Further, for example, in a case where the detector includes the sensor 363, as shown in FIG. 8, when the rotation axis of the substrate placing plate 318 tilts or when the substrate placing plate 318 bends (that is, the substrate placing plate 318 sags in the direction of gravity), the distance 318c between the substrate placing plate 318 and the heater 380 becomes non-constant (non-uniform), and such a state is detected by the sensor 363. Therefore, by monitoring a result (detection result) detected by the sensor 363, it is possible to detect the presence or absence of the abnormality in the rotation state of the substrate placing plate 318 (in particular, a variation in the distance from the heater 380 due to the tilt of the rotation axis thereof or the bending of the substrate placing plate 318). For example, the same also applies to a case where a distance detection of the gap between the substrate placing plate 318 and at least one among the nozzles 341, 342, 344 and 345 is performed.

Further, for example, in a case where the number of rotations or the rotation speed of the substrate placing plate 318 is monitored by the rotation meter 319f serving as the detector or in a case where the amount of the power supplied to the electric motor of the operating structure 319b, when the occurrence of the rotational fluctuation of the substrate placing plate 318 is monitored, such a state is detected. Therefore, by monitoring a result (detection result) using the detector, it is possible to detect the presence or absence of the abnormality in the rotation state of the substrate placing plate 318 (for example, the rotational fluctuation due to a motor trouble).

In addition, for example, in a case where the detector includes the vibration sensor, when the defect in the bearing (such as a fluid seal) of the shaft 322 or the support shaft 319a occurs or when the eccentricity of the rotation axis occurs, such a state is detected by the vibration sensor. Therefore, by monitoring a result (detection result) detected by the vibration sensor, it is possible to detect the presence or absence of the abnormality in the rotation state of the substrate placing plate 318 (in particular, the defect in the bearing or the eccentricity of the rotation axis).

The rotation state monitoring of the substrate support 317 may be performed by using at least one among the examples mentioned above, and preferably, by using the examples mentioned above.

### Execution Timing

The rotation state monitoring of the substrate support 317 may be performed at an execution timing described below.

As an example of the execution timing for the rotation state monitoring, the detector may detect the rotation state of the substrate support 317 before the apparatus (that is, the substrate processing apparatus 200) is started up. The term “before the apparatus is started up” refers to a time before the substrate processing is started in the substrate processing apparatus 200. Specifically, the rotation state of the substrate support 317 is detected before the substrate processing apparatus 200 starts operating (for example, when a test run of the substrate processing apparatus 200 is performed). By detecting the rotation state at such an execution timing, even when a difference in the rotation state occurs due to a machine difference in the substrate processing apparatus 200, it is possible to accurately grasp the difference due to the machine difference.

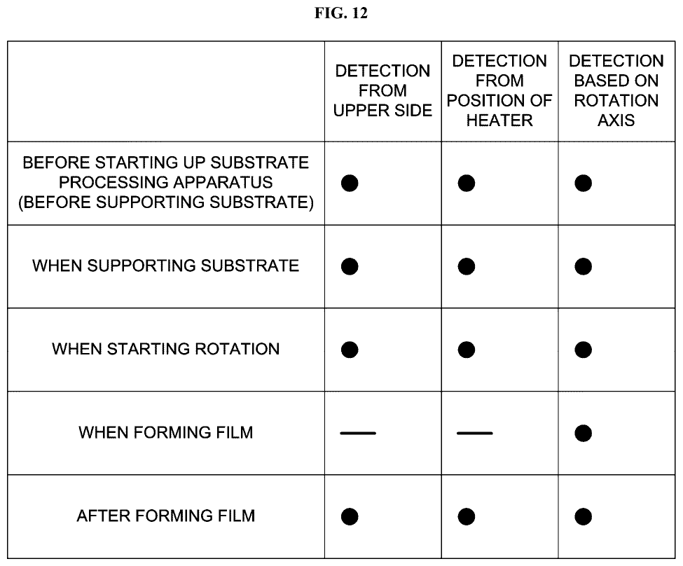

The rotation state monitoring may be performed while the substrate processing apparatus 200 is in operation. FIG. 12 is a diagram schematically illustrating specific examples of the execution timing of the rotation state monitoring while operating the substrate processing apparatus 200 according to the present embodiments.

For example, consider a case where the rotation state monitoring of the substrate support 317 is performed from an upper side of the substrate support 317, such as by detecting the distance (gap) between the substrate support 317 (that is, the substrate placing plate 318) and at least one among the nozzles 341, 342, 344 and 345. In such a case, the rotation state monitoring of the substrate support 317 may be performed at at least one selected from the group of: a timing before the substrate placing plate 318 supports the substrate 100 in the substrate loading and placing step; a timing at which the substrate placing plate 318 supports the substrate 100 in the substrate loading and placing step; a timing at which the rotation of the substrate placing plate 318 starts in the step S110 of starting the rotation of the substrate placing plate 318; and a timing after the film is formed on the substrate 100 in the film forming step S130.

Further, for example, consider a case where the rotation state monitoring of the substrate support 317 is performed from the position of the heater 380, such as by detecting the distance (gap) between the substrate support 317 (that is, the substrate placing plate 318) and the heater 380. In such a case, similarly, the rotation state monitoring of the substrate support 317 may be performed at at least one selected from the group of: the timing before the substrate placing plate 318 supports the substrate 100 in the substrate loading and placing step; the timing at which the substrate placing plate 318 supports the substrate 100 in the substrate loading and placing step; the timing at which the rotation of the substrate placing plate 318 starts in the step S110 of starting the rotation of the substrate placing plate 318; and the timing after the film is formed on the substrate 100 in the film forming step S130.

Further, for example, consider a case where the rotation state monitoring of the substrate support 317 is performed mainly based on the rotation axis of the substrate placing plate 318, such as by using the sensor 361 or the sensor 362. In such a case, similarly, the rotation state monitoring of the substrate support 317 may be performed at at least one selected from the group of: the timing before the substrate placing plate 318 supports the substrate 100 in the substrate loading and placing step; the timing at which the substrate placing plate 318 supports the substrate 100 in the substrate loading and placing step; the timing at which the rotation of the substrate placing plate 318 starts in the step S110 of starting the rotation of the substrate placing plate 318; a timing at which the film is being formed on the substrate 100 in the film forming step S130; and the timing after the film is formed on the substrate 100 in the film forming step S130.

When the rotation state is detected at such timings exemplified above, even when a change in the rotation state occurs over time while the substrate processing apparatus 200 is in operation, it is possible to accurately grasp the change.

When the rotation state monitoring is performed while the substrate processing apparatus 200 is in operation, it is preferable to detect the rotation state of the substrate support 317 with the gas being supplied through the gas supplier. In the present embodiments, the gas may refer to one of the process gases or may refer to the inert gas. More specifically, when detecting the rotation state of the substrate support 317, the gas is supplied to the process chamber 301 such that a pressure in the process chamber 301 reaches a pressure at which the substrate 100 is processed in the process chamber 301. For example, when the rotation state is detected under the same conditions as when the substrate 100 is processed in the substrate processing, it is possible to detect the rotation state with a high accuracy. For example, when an apparatus maintenance work is performed, the inner pressure of the process chamber 301 may be lower than during the substrate processing. In such a case, the rotation state of the substrate support 317 may be different from that during the substrate processing when the rotation state monitoring is performed. In consideration of such a case, it is preferable to monitor the rotation state of the substrate support 317 under the same conditions (environment) as when the substrate processing is performed.

### Control of Rotation State

After the rotation state monitoring is performed, the controller 400 serving as the control structure controls the rotation state of the substrate support 317 based on the detection result by the detector obtained by the rotation state monitoring.

Specifically, the controller 400 controls the rotation state of the substrate support 317 to be constant based on the detection result by the detector. For example, when parameters (such as the tilt of the rotation axis of the substrate placing plate 318, the bending of the substrate placing plate 318, the distance between the substrate placing plate 318 and the heater 380, the distance between the substrate placing plate 318 and at least one among the nozzles 341, 342, 344 and 345 and the rotational fluctuation of the substrate placing plate 318) are respectively within predetermined allowable ranges and are maintained in such a state, it can be said that the rotation state of the substrate support 317 is constant.

For example, when the detector detects the abnormality in which the number of rotations or the rotation speed of the substrate placing plate 318 goes beyond the allowable range related thereto, the controller 400 issues an operation instruction to the operating structure 319b of the elevator/rotator 319 to recover from the abnormality (rotation abnormality), that is, to limiting the rotation within the allowable range related thereto. When the rotation of the substrate placing plate 318 slows down, the time duration for the substrate 100 to pass through each of the regions 306a, 307a, 306b and 307b may increase, and thereby, a substrate processing time in each of the regions 306a, 307a, 306b and 307b may also increase. As a result, a desired processing may not be achieved for each of the substrates 100. In contrast, when the substrate placing plate 318 is controlled to maintain a constant rotation, a gas supply amount in each of the regions 306a, 307a, 306b and 307b can be maintained constant, and the desired processing can be achieved for each of the substrates 100. When such a control of the rotation state is performed based on the detection result obtained by the rotation state monitoring before the apparatus is started up, it is possible to eliminate the rotation abnormality caused by the machine difference in the substrate processing apparatus 200, and it is also possible to start up the apparatus in a state where such a machine difference is taken into consideration. Further, when such a control of the rotation state is performed based on the detection result obtained by the rotation state monitoring when the apparatus is in operation, it is possible to appropriately respond to the rotation abnormality which may occur due to the change over time.

In addition, for example, in a case where the heater 380 is divided into the plurality of zones, when the detector detects the abnormality in which the tilt of the rotation axis of the substrate placing plate 318 goes beyond the allowable range related thereto, the controller 400 issues an operation instruction to the heater temperature controller 387 to lower a heater temperature in the zone where the distance between the substrate placing plate 318 and the heater 380 is close. The same also applies to a case where the abnormality in which the bending of the substrate placing plate 318 occurs is detected, or a case where the abnormality in which the distance between the substrate placing plate 318 and the heater 380 goes beyond the allowable range related thereto is detected. By performing such a heater zone control described above, it is possible to recover from the rotation abnormality of the substrate placing plate 318, and it is also possible to perform the desired processing for each of the substrates 100.

In addition, for example, in a case where the posture controller 350 is provided, when the detector detects the abnormality in which the tilting of the rotation axis of the substrate placing plate 318 goes beyond the allowable range related thereto, the controller 400 issues an operation instruction to the tilt regulator 353 to adjust the posture of the substrate support 317 (in particular, the tilt of the rotation axis caused by the shaft 322). By performing a control to adjust an angle of the rotation axis, it is possible to set the substrate support 317 to be at a predetermined substrate processing angle (that is, to set the angle of the rotation axis within the allowable range related thereto). Thereby, it is possible to recover from the rotation abnormality of the substrate placing plate 318. When such a control of the posture is performed based on the detection result obtained by the rotation state monitoring before the apparatus is started up, it is possible to eliminate the rotation abnormality caused by the machine difference in the substrate processing apparatus 200, and it is also possible to start up the apparatus in a state where such a machine difference is taken into consideration. In particular, the tilt of the rotation axis of the substrate placing plate 318 is likely to occur due to the machine difference of the substrate processing apparatus 200 for the convenience of manufacturing the apparatus. However, such a tilt (that is, a difference in a degree of the tilt) can be absorbed by the control of the posture. Further, when such a control of the posture is performed based on the detection result obtained by the rotation state monitoring when the apparatus is in operation, it is possible to appropriately respond to the rotation abnormality which may occur due to the change over time.

In addition, for example, in a case where the posture controller 350 is provided, the controller 400 may use a machine learning to control the posture of the substrate support 317 by the posture controller 350. When the machine learning is used, a storage (memory or a recording structure) configured to store and accumulate information about the detection result by the detector may be prepared in the controller 400 or in a location accessible to the controller 400. For example, the information stored and accumulated in the storage (that is, the information about the detection result by the detector) may include: information about the rotation state of the substrate placing plate 318 identified from the detection result by the detector; information about process conditions of the substrate processing when the information stored in the storage was obtained; information about a processing result of the substrate processing; and the like. Then, based on the information stored in the storage, the controller 400 analyzes the rotation state of the substrate placing plate 318 and an apparatus operation history (an execution history of the substrate processing) by the machine learning, and identifies model data about the posture of the substrate support 317 from an analysis result. Once the model data has been identified, the controller 400 issues an operation instruction to the tilt regulator 353 to adjust the posture of the substrate support 317 (in particular, the tilt of the rotation axis caused by the shaft 322) based on the model data identified as described above prior to a start of a subsequent substrate processing. In a manner described above, by using the machine learning to control the posture of the substrate support 317, it is possible to reflect other information (such as a history information) in addition to the detection result by the detector for the control ‘the posture, which is preferable for appropriately performing the substrate processing.

When the detector detects the abnormality in the rotation state of the substrate support 317, in addition to or instead of the control mentioned above, the controller 400 may perform a transfer control such that the substrate 100 transferred into the process chamber 301 is unloaded from the process chamber 301. By performing such a transfer control of unloading of the substrate 100 in a manner described above, it is possible to distinguish a substrate (which may not have been subjected to the desired processing due to the abnormality in the rotation state) among the substrates 100 from a normal substrate among the substrates 100.

### (4) Effects According to Present Embodiments

According to the present embodiments, it is possible to obtain one or more of the effects described below.
(a) According to the present embodiments, when each of the substrates 100 is processed while rotating the substrate support 317 supporting the substrates 100, the detector detects the rotation state of the substrate support 317. Thus, even when the abnormality occurs in the rotation state of the substrate support 317, such an abnormality is detected by the detector. Thereby, it is possible to eliminate effects of the abnormality in the rotation state causing the variation in the processing quality of each of the substrates 100 when each of the substrates 100 is processed. In other words, when the plurality of substrates 100 are processed while being rotated, it is possible to obtain the desired processing quality for each of the substrates 100.
(b) According to the present embodiments, the heater 380 is disposed so as to face the substrate placing plate 318 serving as a rotator constituting the substrate support 317, and the detector detects the rotation state of the substrate placing plate 318. Thus, when the abnormality occurs in the rotation state of the substrate placing plate 318, a variation may occur in a relationship between the heater 380 and each of the substrates 100 on the substrate placing plate 318. However, such an abnormality is detected by the detector. Therefore, it is possible to eliminate effects of such a variation. In other words, when the plurality of substrates 100 placed on the substrate placing plate 318 are processed while rotating the substrate placing plate 318, it is possible to obtain the desired processing quality for each of the substrates 100.
(c) According to the present embodiments, as described above, when the detector includes at least one selected from the group of the sensor 361 (which is configured to detect the position of the edge 318a of the substrate placing plate 318), the sensor 362 (which is arranged such that the sensing light passes along the plate surface of the substrate placing plate 318) and the sensor 363 (which is configured to detect the distance (gap 318c) between the substrate placing plate 318 and the heater 380, it is possible to reliably detect the tilt or the bending of the substrate placing plate 318.
(d) According to the present embodiments, as described above, when the detector is configured to detect the change in the power supplied to the electric motor, it is possible to reliably detect the rotational fluctuation when the substrate placing plate 318 is rotated.
(e) According to the present embodiments, based on the detection result by the detector, the controller 400 controls the rotation state of the substrate support 317. Therefore, even when the abnormality occurs in the rotation state of the substrate support 317, it is possible to process each of the substrates 100 while controlling the rotation state to prevent the variation in the processing quality due to the abnormality in the rotation state. Thereby, it is possible to obtain the desired processing quality for each of the substrates 100.
(f) According to the present embodiments, as described above, when the rotation state monitoring of obtaining the detection result (which is detected by the detector before the apparatus is started up) is performed, even when the difference in the rotation state occurs due to the machine difference in the substrate processing apparatus 200, it is possible to accurately grasp the difference due to the machine difference.
(g) According to the present embodiments, in a case where the rotation state of the substrate support 317 is controlled, as described above, when the rotation state of the substrate support 317 is controlled to be constant, it is possible to reliably eliminate the effects of the abnormality causing the variation in the processing quality of each of the substrates 100.
(h) According to the present embodiments, as described above, in a case where the heater 380 is divided into the plurality of zones, when the temperature control is individually performed for each of the plurality of zones based on the detection result by the detector, it is possible to recover from the rotation abnormality of the substrate placing plate 318 and it is also possible to perform the desired processing on the substrate 100.
(i) According to the present embodiments, as described above, in a case where the posture controller 350 is provided, when the posture of the substrate support 317 (in particular, the tilt of the rotation axis caused by the shaft 322) is adjusted based on the detection result by the detector to set the substrate support 317 to be at the predetermined substrate processing angle (that is, to set the angle of the rotation axis within the allowable range related thereto), it is possible to recover from the rotation abnormality of the substrate placing plate 318. Further, when such a control of the posture is performed based on the detection result obtained by the rotation state monitoring before the apparatus is started up, it is possible to eliminate the rotation abnormality caused by the machine difference in the substrate processing apparatus 200, and it is also possible to start up the apparatus in the state where the machine difference is taken into consideration.
(j) According to the present embodiments, as described above, in a case where the detector detects the rotation state of the substrate support 317 with the gas being supplied through the gas supplier, it is possible to detect the rotation state under the same conditions as when the substrate 100 is processed in the substrate processing. Thereby, it is possible to detect the rotation state with a high accuracy.
(k) According to the present embodiments, as described above, in a case where the detector detects the rotation state of the substrate support 317, when the gas is supplied to the process chamber 301 such that the pressure in the process chamber 301 reaches a pressure at which the substrate 100 is processed in the process chamber 301, it is possible to detect the rotation state under the same conditions as when the substrate 100 is processed in the substrate processing. Thereby, it is possible to detect the rotation state with a high accuracy.

### (5) Modified Example and Other Embodiments

While the technique of the present disclosure is described in detail by way of the embodiments mentioned above, the technique of the present disclosure is not limited thereto. The technique of the present disclosure may be modified in various ways without departing from the scope thereof.

For example, the embodiments mentioned above are described by way of an example in which the substrate placing plate 318 (on which the substrates 100 are placed) is rotated, that is, an example in which each of the substrates 100 revolves (is rotated) around a center of the substrate placing plate 318. However, the technique of the present disclosure is not limited thereto. For example, each of the substrates 100 may be supported by the substrate placing plate 318 such that each of the substrates 100 can be rotated while revolving. In such a case, the substrate support 317 may include: a revolving structure (for example, the substrate placing plate 318) configured to support the substrates 100 such that the substrates 100 can revolve around the center of the substrate placing plate 318; and a rotating structure configured to support the substrates 100 such that each of the substrates 100 can be rotated around a center of each of the substrates 100. The rotating structure may be configured using known technology. When the substrate support 317 includes the revolving structure and the rotating structure as described above, the detector is configured to be capable of detecting a rotation state of one of the revolving structure and the rotating structure, and preferably capable of detecting the rotation states of both of the revolving structure and the rotating structure. Thereby, it is possible to respond not only to the abnormality in the rotation state of the revolving structure but also to the abnormality in the rotation state of the rotating structure. Thus, it is extremely preferable for performing the desired processing on the substrate 100.

For example, the embodiments mentioned above are described by way of an example in which the DCS gas is used as the source gas (first gas). However, the technique of the present disclosure is not limited thereto. For example, as the source gas, in addition to or instead of the DCS gas, a chlorosilane source gas containing a Si—Cl bond (silicon-chlorine bond) such as hexachlorodisilane (Si₂C₆, abbreviated as HCDS) gas, monochlorosilane (SiH₃Cl, abbreviated as MCS) gas, trichlorosilane (SiHCl₃, abbreviated as TCS) gas, tetrachlorosilane (SiCl₄, abbreviated as STC) gas and octachlorotrisilane (Si₃Cl₈, abbreviated as OCTS) gas may be used.

For example, the embodiments mentioned above are described by way of an example in which the NH₃ gas is used as the reactive gas (second gas). However, the technique of the present disclosure is not limited thereto. For example, as the reactive gas, in addition to or instead of the NH₃ gas, a hydrogen nitride-based gas containing a N—H bond (nitrogen—hydrogen bond) such as diazene (N₂H₂) gas, hydrazine (N₂H₄) gas and N₃H₈ gas may be used.

For example, the embodiments mentioned above are described by way of an example in which the N₂ gas is used as the inert gas. However, the technique of the present disclosure is not limited thereto. For example, as the inert gas, in addition to or instead of the N₂ gas, a rare gas such as argon (Ar) gas, helium (He) gas, neon (Ne) gas and xenon (Xe) gas may be used.

For example, the embodiments mentioned above are described by way of an example in which a film forming process of forming the film on the substrate 100 is performed as the substrate processing. However, the technique of the present disclosure is not limited thereto. For example, the technique of the present disclosure may also be applied to other processes as long as the supply and exhaust of the gas is preferably performed. For example, the technique of the present disclosure may also be applied to a process such as a diffusion process, an oxidation process, a nitridation process, an oxynitridation process, a reduction process, an oxidation-reduction process, an etching process and a heating process.

According to some embodiments of the present disclosure, it is possible to obtain a desired processing quality for each of the plurality of substrates even when the plurality of substrates are processed while being rotated.

What is claimed is:

1. A substrate processing apparatus comprising:
a process chamber in which a plurality of substrates are processed;
a gas supplier configured to be capable of supplying a gas to the process chamber;
a substrate support provided in the process chamber so as to be rotatable and configured to be capable of supporting the plurality of substrates in a circumferential arrangement; and
a detector configured to detect a rotation state of the substrate support.

2. The substrate processing apparatus of claim 1, further comprising:
a heater configured to heat the plurality of substrates,
wherein the substrate support comprises:
a rotating structure of a plate shape configured to support the plurality of substrates; and
a support shaft configured to rotatably support the rotating structure,
wherein the heater is provided to face the rotating structure, and
wherein the detector is further configured to detect a presence or absence of an abnormality in a state of the rotating structure.

3. The substrate processing apparatus of claim 2, wherein the detector comprises a sensor configured to detect a position of an edge of the rotating structure.

4. The substrate processing apparatus of claim 3, wherein the sensor is provided at a plurality of locations in a circumferential direction of the rotating structure in accordance with an outer peripheral shape of the rotating structure.

5. The substrate processing apparatus of claim 2, wherein the detector comprises a sensor arranged such that a sensing light passes along a plate surface of the rotating structure.

6. The substrate processing apparatus of claim 2, wherein the detector comprises a sensor configured to detect a distance between the rotating structure and the heater.

7. The substrate processing apparatus of claim 2, wherein the detector is further configured to detect a tilt of the rotating structure, a bending of the rotating structure or both of the tilt of the rotating structure and the bending of the rotating structure.

8. The substrate processing apparatus of claim 2, further comprising:
an electric motor used as a drive source configured to rotate the support shaft,
wherein the detector is further configured to detect a change in a power supplied to the electric motor.

9. The substrate processing apparatus of claim 2, wherein the heater is divided into a plurality of zones along a circumferential direction of the rotating structure, and is further configured to be capable of individually adjusting a temperature of each of the plurality of zones based on a detection result detected by the detector.

10. The substrate processing apparatus of claim 1, further comprising:
a controller configured to be capable of controlling the rotation state of the substrate support based on a detection result detected by the detector.

11. The substrate processing apparatus of claim 10, wherein the controller is further configured to be capable of controlling the rotation state of the substrate support to be constant based on the detection result detected by the detector.

12. The substrate processing apparatus of claim 1, wherein the detector is further configured to detect the rotation state of the substrate support before the substrate processing apparatus is started up.

13. The substrate processing apparatus of claim 1, further comprising:
a posture controller configured to be capable of adjusting an angle of a shaft supporting the substrate support based on a detection result detected by the detector to set the substrate support to be at a predetermined substrate processing angle.

14. The substrate processing apparatus of claim 13, wherein the posture controller is further configured to be capable of adjusting the angle of the shaft based on the detection result detected by the detector before the substrate processing apparatus is started up.

15. The substrate processing apparatus of claim 13, further comprising:
a storage configured to store and accumulate information about the detection result detected by the detector,
wherein the posture controller is further configured to be capable of adjusting the angle of the shaft before the plurality of substrates are processed in the process chamber based on an analysis result of the information stored in the storage.

16. The substrate processing apparatus of claim 1, wherein the detector is further configured to detect the rotation state of the substrate support with the gas being supplied through the gas supplier.

17. The substrate processing apparatus of claim 16, wherein the gas supplier is further configured to supply the gas into the process chamber when the detector detects the rotation state of the substrate support such that a pressure in the process chamber reaches a pressure at which the plurality of substrates are processed in the process chamber.

18. The substrate processing apparatus of claim 1, wherein the substrate support comprises:
a first rotating structure configured to rotate the plurality of substrates around a center of the first rotating structure; and
a second rotating structure configured to rotate each of the plurality of substrates around a center of each of the plurality of substrates,
wherein the detector is further configured to be capable of detecting a rotation state of the first rotating structure or a rotation state of the second rotating structure, or both.

19. A rotation state detection method comprising:
(a) rotating a substrate support in a process chamber in which a plurality of substrates are processed, wherein the substrate support is configured to be capable of supporting the plurality of substrates in a circumferential arrangement; and
(b) detecting a rotation state of the substrate support.

20. A method of manufacturing a semiconductor device, comprising the method according to claim 19.

21. A non-transitory computer-readable recording medium storing a program that causes, by a computer, a substrate processing apparatus to perform:
(a) rotating a substrate support in a process chamber in which a plurality of substrates are processed, wherein the substrate support is configured to be capable of supporting the plurality of substrates in a circumferential arrangement; and
(b) detecting a rotation state of the substrate support.
